(19) United States
(12) Patent Application Publication
(10) Pub. No.: US 2026/0120777 A1
(43) Pub. Date: Apr. 30, 2026

(54) STORAGE DEVICE STORING TEMPERATURE RANGE INFORMATION AT TIME POINT OF PROGRAMMING DATA AND METHOD FOR OPERATING THE STORAGE DEVICE

(71) Applicant: SK hynix Inc., Icheon-si (KR)

(72) Inventors: Hyo Byung Han, Icheon-si (KR); Young Wu Choi, Icheon-si (KR)

(21) Appl. No.: 19/081,913

(22) Filed: Mar. 17, 2025

(30) Foreign Application Priority Data
Oct. 28, 2024 (KR) 10-2024-0148158

(51) Int. Cl. G11C 16/34; G11C 16/10

(52) U.S. Cl. CPC G11C 16/3418; G11C 16/102; G11C 16/349

(57) ABSTRACT

A storage device may include a memory and a controller. The memory may include a plurality of memory units, and each of the plurality of memory units may include a plurality of first memory cells and a plurality of second memory cells. The controller may program target data into first memory cells within a target memory unit among the plurality of memory units, may program metadata corresponding to the target data into second memory cells within the target memory unit, and may program first temperature range information, representing a temperature range at a time of programming the target data, into second memory cells within the target memory unit.

### CROSS-REFERENCE TO RELATED APPLICATION

The present application claims priority under 35 U.S.C. § 119 (a) to Korean Patent Application No. 10-2024-0148158 filed in the Korean Intellectual Property Office on Oct. 28, 2024, which is incorporated herein by reference in its entirety.

### BACKGROUND

### 1. Technical Field

Embodiments of the present disclosure relate to a storage device that stores temperature range information at the time when data is programmed, and a method for operating the storage device.

### 2. Related Art

A storage device is a device for storing data according to a request from an external device such as a computer, a mobile terminal (e.g., a smart phone or tablet), or the like.

A storage device may include a memory for storing data therein and a controller for controlling the memory. The memory may be a volatile memory or a non-volatile memory. The controller may receive a command from an external device (i.e., a host), and execute or control operations to read, write, or erase data in the memory included in the storage device according to the received command.

The reliability of data stored in the storage device decreases with read operations. This degradation may vary depending on a temperature at the time when the data is programmed and a temperature at the time when the data is read.

Therefore, in order to determine an appropriate time for performing a defense operation to restore the reliability of data, the storage device needs to consider both the temperature at the time when the data is programmed and the temperature at the time when the data is read.

### SUMMARY

Various embodiments of the present disclosure are directed to providing a storage device and a method for operating the storage device, designed to optimize the timing of a defense operation for restoring the reliability of programmed data by accounting for variations in read counts based on both a temperature at the time when data is programmed and a temperature at the time when data is read.

In an aspect, a storage device may include: a memory including a plurality of memory units, each of the plurality of memory units including a plurality of first memory cells and a plurality of second memory cells; and a controller configured to program target data into first memory cells within a target memory unit among the plurality of memory units, program metadata corresponding to the target data into second memory cells within the target memory unit and program first temperature range information, representing a temperature range at a time of programming the target data, into second memory cells within the target memory unit.

In another aspect, a method for operating a storage device may include: determining a target memory unit among a plurality of memory units included in a memory, each of the plurality of memory units including a plurality of first memory cells and a plurality of second memory cells; programming target data into first memory cells within the target memory unit; programming metadata corresponding to the target data to second memory cells within the target memory unit; and programming first temperature range information, representing a temperature range at a time of programming the target data, into second memory cells within the target memory unit.

According to the embodiments of the present disclosure, by accounting for variations in read counts based on the temperature at the time when data is programmed and the temperature at the time when data is read, it is possible to optimize the timing of the defense operation to restore the reliability of programmed data.

### BRIEF DESCRIPTION OF THE DRAWINGS

FIG. 1 illustrates a storage device according to an embodiment of the present disclosure.

FIG. 2 illustrates a memory of FIG. 1.

FIG. 3 illustrates a storage device according to an embodiment of the present disclosure.

FIG. 4 illustrates an operation in which the storage device according to the embodiment of the present disclosure programs target data into a target memory unit.

FIG. 5 illustrates data programmed into the target memory unit according to an embodiment of the present disclosure.

FIG. 6 illustrates an example of the target memory unit according to an embodiment of the present disclosure.

FIG. 7 illustrates an example in which the storage device according to the embodiment of the present disclosure determines temperature range information.

FIG. 8 illustrates an operation in which the storage device according to the embodiment of the present disclosure reads target data from the target memory unit.

FIG. 9 illustrates an example of an operation in which the storage device according to the embodiment of the present disclosure determines an increase amount in read count.

FIG. 10 illustrates a method for operating a storage device according to an embodiment of the present disclosure.

### DETAILED DESCRIPTION

Hereinafter, embodiments of the present disclosure are described in detail with reference to the accompanying drawings. Throughout the specification, reference to “an embodiment,” “another embodiment” or the like is not necessarily to only one embodiment, and different references to any such phrase are not necessarily limited to the same embodiment(s). The term “embodiments” when used herein does not necessarily refer to all embodiments.

Various embodiments of the present disclosure are described below in more detail with reference to the accompanying drawings. However, the present disclosure may be embodied in different forms and variations, and should not be construed as being limited to the embodiments set forth herein. Rather, the described embodiments are provided so that this disclosure will be thorough and complete, and will fully convey the present disclosure to those skilled in the art to which this disclosure pertains. Throughout the disclosure, like reference numerals refer to like parts throughout the various figures and embodiments of the present disclosure.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing methods herein.

When implemented at least partially in software, the controllers, processors, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device.

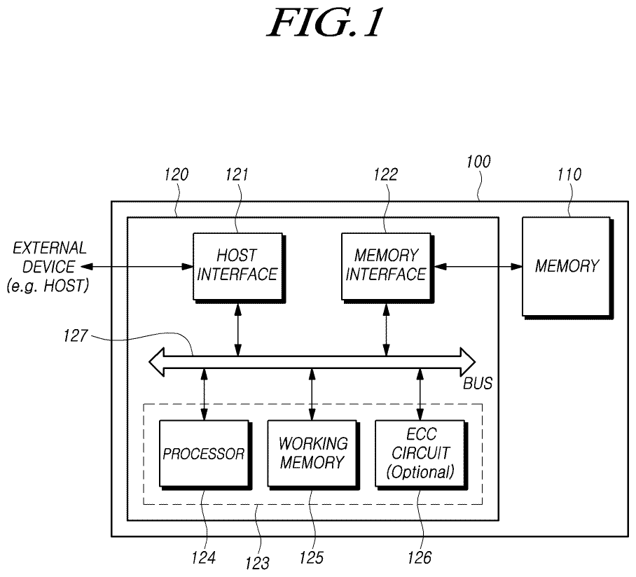

FIG. 1 illustrates a storage device 100 according to an embodiment of the disclosure.

Referring to FIG. 1, the storage device 100 may include a memory 110 that stores data and a controller 120 that controls the memory 110.

The memory 110 includes a plurality of memory blocks, and operates under the control of the controller 120. Operations of the memory 110 may include, for example, a read operation, a program operation (also referred to as a write operation) and an erase operation.

The memory 110 may include a memory cell array including a plurality of memory cells (also simply referred to as “cells”) that store data.

For example, the memory 110 may be realized in various types of memory such as a DDR SDRAM (double data rate synchronous dynamic random access memory), an LPDDR4 (low power double data rate 4) SDRAM, a GDDR (graphics double data rate) SDRAM, an LPDDR (low power DDR), an RDRAM (Rambus dynamic random access memory), a NAND flash memory, a 3D NAND flash memory, a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), and so forth.

The memory 110 may be implemented as a three-dimensional array structure. For example, embodiments of the present disclosure may be applied to a charge trap flash (CTF) in which a charge storage layer is configured by a dielectric layer and a flash memory in which a charge storage layer is configured by a conductive floating gate.

The memory 110 may receive a command and an address from the controller 120 and may access an area in the memory cell array that is selected by the address. In other words, the memory 110 may perform an operation indicated by the command, on the area selected by the address.

The memory 110 may perform a program operation, a read operation or an erase operation. For example, when performing the program operation, the memory 110 may program data to the area selected by the address. When performing the read operation, the memory 110 may read data from the area selected by the address. In the erase operation, the memory 110 may erase data stored in the area selected by the address.

The controller 120 may control write (or program), read, erase and background operations for the memory 110. For example, background operations may include at least one from among a garbage collection (GC) operation, a wear leveling (WL) operation, a read reclaim (RR) operation, a bad block management (BBM) operation, and so forth.

The controller 120 may control the operation of the memory 110 according to a request from a device (e.g., a host) located outside the storage device 100. The controller 120, however, also may control the operation of the memory 110 regardless of a request from the host.

The host may be a computer, an ultra-mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a computer network, one of various electronic devices configuring a telematics network, an RFID (radio frequency identification) device, and a mobility device (e.g., a vehicle, a robot or a drone) capable of driving under human control or autonomous driving, as non-limiting examples. Alternatively, the host may be a virtual reality (VR) device providing 2D or 3D virtual reality images or an augmented reality (AR) device providing augmented reality images. The host may be any one of various electronic devices that require the storage device 100 capable of storing data. The host may include at least one operating system (OS). The operating system may generally manage and control the function and operation of the host, and may control interoperability between the host and the storage device 100. The operating system may be classified into a general operating system and a mobile operating system depending on the mobility of the host.

The controller 120 and the host may be devices that are separated from each other, or the controller 120 and the host may be integrated into one device. Hereunder, for the sake of convenience in explanation, descriptions will describe the controller 120 and the host as devices that are separated from each other.

Referring to FIG. 1, the controller 120 may include a memory interface 122 and a control circuit 123, and may further include a host interface 121.

The host interface 121 provides an interface for communication with the host. For example, the host interface 121 provides an interface that uses at least one from among various interface protocols such as a USB (universal serial bus) protocol, an MMC (multimedia card) protocol, a PCI (peripheral component interconnection) protocol, a PCI-E (PCI-express) protocol, an ATA (advanced technology attachment) protocol, a serial-ATA protocol, a parallel-ATA protocol, an SCSI (small computer system interface) protocol, an ESDI (enhanced small disk interface) protocol, an IDE (integrated drive electronics) protocol and a private protocol.

When receiving a command from the host, the control circuit 123 may receive the command through the host interface 121, and may perform an operation of processing the received command.

The memory interface 122 may be coupled with the memory 110 to provide an interface for communication with the memory 110. That is to say, the memory interface 122 may be configured to provide an interface between the memory 110 and the controller 120 under the control of the control circuit 123.

The control circuit 123 performs the general control operations of the controller 120 to control the operation of the memory 110. To this end, for instance, the control circuit 123 may include at least one of a processor 124 and a working memory 125, and may optionally include an error detection and correction circuit (ECC circuit) 126.

The processor 124 may control general operations of the controller 120, and may perform a logic calculation. The processor 124 may communicate with the host through the host interface 121, and may communicate with the memory 110 through the memory interface 122.

The processor 124 may execute logical operations required to perform the function of a flash translation layer (FTL). The processor 124 may translate a logical block address (LBA), provided by the host, into a physical block address (PBA) through the flash translation layer. The flash translation layer may receive the logical block address and translate the logical block address into the physical block address, by using a mapping table.

There are various address mapping methods of the flash translation layer, depending on a mapping unit. Representative address mapping methods include a page mapping method, a block mapping method and a hybrid mapping method.

The processor 124 may randomize data received from the host. For example, the processor 124 may randomize data received from the host by using a set randomizing seed. The randomized data may be provided to the memory 110, and may be programmed to a memory cell array of the memory 110.

In a read operation, the processor 124 may derandomize data received from the memory 110. For example, the processor 124 may derandomize data received from the memory 110 by using a derandomizing seed. The derandomized data may be outputted to the host.

The processor 124 may execute firmware to control the operation of the controller 120. Namely, in order to control the general operation of the controller 120 and perform a logic calculation, the processor 124 may execute (or drive) firmware loaded in the working memory 125 upon booting. Hereafter, an operation of the storage device 100 according to embodiments of the disclosure will be described as implementing a processor 124 that executes firmware in which the corresponding operation is defined.

Firmware, as a program to be executed in the storage device 100 to drive the storage device 100, may include various functional layers. For example, the firmware may include binary data in which codes for executing the functional layers, respectively, are defined.

For example, the firmware may include at least one from among a flash translation layer, which performs a translating function between a logical address requested to the storage device 100 from the host and a physical address of the memory 110; a host interface layer (HIL), which serves to analyze a command requested to the storage device 100 as a storage device from the host and transfer the command to the flash translation layer; and a flash interface layer (FIL), which transfers a command, instructed from the flash translation layer, to the memory 110.

Such firmware may be loaded in the working memory 125 from, for example, the memory 110 or a separate nonvolatile memory (e.g., a ROM or a NOR Flash) located outside the memory 110. The processor 124 may first load all or a part of the firmware in the working memory 125 when executing a booting operation after power-on.

The processor 124 may perform a logic calculation, which is defined in the firmware loaded in the working memory 125, to control the general operation of the controller 120. The processor 124 may store a result of performing the logic calculation defined in the firmware, in the working memory 125. The processor 124 may control the controller 120 according to a result of performing the logic calculation defined in the firmware such that the controller 120 generates a command or a signal. When a part of firmware, in which a logic calculation to be performed is defined, is stored in the memory 110, but not loaded in the working memory 125, the processor 124 may generate an event (e.g., an interrupt) for loading the corresponding part of the firmware into the working memory 125 from the memory 110.

The processor 124 may load metadata necessary for driving firmware from the memory 110. The metadata, as data for managing the memory 110, may include for example management information on user data stored in the memory 110.

Firmware may be updated while the storage device 100 is manufactured or while the storage device 100 is operating. The controller 120 may download new firmware from the outside of the storage device 100 and update existing firmware with the new firmware.

To drive the controller 120, the working memory 125 may store necessary firmware, a program code, a command and data. The working memory 125 may be a volatile memory that includes, for example, at least one from among an SRAM (static RAM), a DRAM (dynamic RAM) and an SDRAM (synchronous DRAM). Meanwhile, the controller 120 may additionally use a separate volatile memory (e.g., SRAM, DRAM) located outside the controller 120 in addition to the working memory 125.

The error detection and correction circuit 126 may detect an error bit of target data, and correct the detected error bit by using an error correction code. The target data may be, for example, data stored in the working memory 125 or data read from the memory 110.

The error detection and correction circuit 126 may decode data by using an error correction code. The error detection and correction circuit 126 may be realized by various code decoders. For example, a decoder that performs unsystematic code decoding or a decoder that performs systematic code decoding may be used.

For example, the error detection and correction circuit 126 may detect an error bit by the unit of a set sector in each of the read data, when each read data is constituted by a plurality of sectors. A sector may mean a data unit that is smaller than a page, which is the read unit of a flash memory. Sectors constituting each read data may be matched with one another using an address.

The error detection and correction circuit 126 may calculate a bit error rate (BER), and may determine whether an error is correctable or not, by sector units. For example, when a bit error rate is higher than a reference value, the error detection and correction circuit 126 may determine that a corresponding sector is uncorrectable or has failed. On the other hand, when a bit error rate is lower than the reference value, the error detection and correction circuit 126 may determine that a corresponding sector is correctable or has passed.

The error detection and correction circuit 126 may perform an error detection and correction operation sequentially for all read data. In the case where a sector included in read data is correctable, the error detection and correction circuit 126 may omit an error detection and correction operation for a corresponding sector for next read data. If the error detection and correction operation for all read data is ended in this way, then the error detection and correction circuit 126 may detect a sector which is uncorrectable in read data last. There may be one or more sectors that are determined to be uncorrectable. The error detection and correction circuit 126 may transfer information (e.g., address information) regarding a sector which is determined to be uncorrectable to the processor 124.

A bus 127 may be configured to provide channels among the components 121, 122, 124, 125, and 126 of the controller 120. The bus 127 may include, for example, a control bus for transferring various control signals, commands and the like, a data bus for transferring various data, and so forth.

Some components among the above-described components 121, 122, 124, 125, and 126 of the controller 120 may be omitted, or some components among the above-described components 121, 122, 124, 125, and 126 of the controller 120 may be integrated into one component. In addition to the above-described components 121, 122, 124, 125, and 126 of the controller 120, one or more other components may be added.

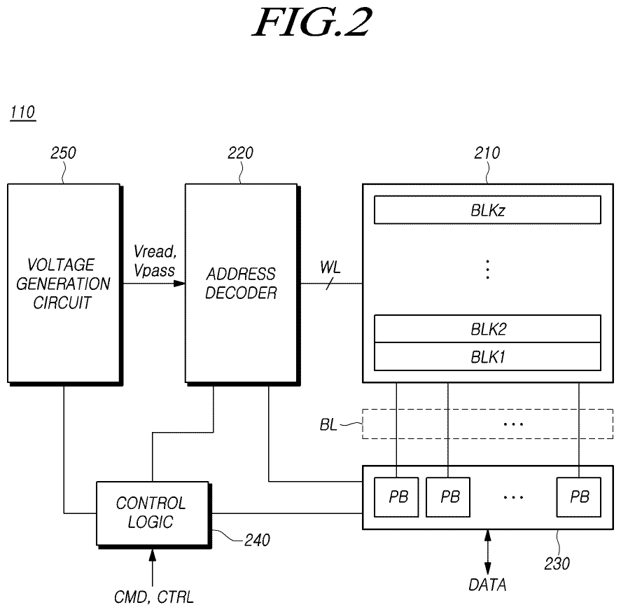

Hereinbelow, the memory 110 will be described in further detail with reference to FIG. 2.

FIG. 2 illustrates the memory 110 of FIG. 1.

Referring to FIG. 2, the memory 110 may include a memory cell array 210, an address decoder 220, a read and write circuit 230, a control logic 240, and a voltage generation circuit 250.

The memory cell array 210 may include a plurality of memory blocks BLK1 to BLKz (where z is a natural number of 2 or greater). In the plurality of memory blocks BLK1 to BLKz, a plurality of word lines WL and a plurality of bit lines BL may be disposed, and a plurality of memory cells may be arranged.

The plurality of memory blocks BLK1 to BLKz may be coupled with the address decoder 220 through the plurality of word lines WL. The plurality of memory blocks BLK1 to BLKz may be coupled with the read and write circuit 230 through the plurality of bit lines BL.

Each of the plurality of memory blocks BLK1 to BLKz may include a plurality of memory cells. For example, the plurality of memory cells may be nonvolatile memory cells, and may be configured by nonvolatile memory cells that have vertical channel structures.

The memory cell array 210 may be configured by a memory cell array of a two-dimensional structure or may be configured by a memory cell array of a three-dimensional structure.

Each of the plurality of memory cells included in the memory cell array 210 may store at least 1-bit data. For instance, each of the plurality of memory cells included in the memory cell array 210 may be a single level cell (SLC) that stores 1-bit data. In another instance, each of the plurality of memory cells included in the memory cell array 210 may be a multi-level cell (MLC) that stores 2-bit data. In still another instance, each of the plurality of memory cells included in the memory cell array 210 may be a triple level cell (TLC) that stores 3-bit data. In yet another instance, each of the plurality of memory cells included in the memory cell array 210 may be a quad level cell (QLC) that stores 4-bit data. In a further instance, the memory cell array 210 may include a plurality of memory cells, each of which stores 5 or more-bit data.

The number of bits of data stored in each of the plurality of memory cells may be dynamically determined. For example, a single-level cell that stores 1-bit data may be changed to a triple-level cell that stores 3-bit data.

Referring to FIG. 2, the address decoder 220, the read and write circuit 230, the control logic 240 and the voltage generation circuit 250 may operate as a peripheral circuit that drives the memory cell array 210.

The address decoder 220 may be coupled to the memory cell array 210 through the plurality of word lines WL.

The address decoder 220 may be configured to operate in response to the control of the control logic 240.

The address decoder 220 may receive an address through an input/output buffer in the memory 110. The address decoder 220 may be configured to decode a block address in the received address. The address decoder 220 may select at least one memory block depending on the decoded block address.

The address decoder 220 may receive a read voltage Vread and a pass voltage Vpass from the voltage generation circuit 250.

The address decoder 220 may apply the read voltage Vread to a selected word line WL in a selected memory block during a read operation, and may apply the pass voltage Vpass to the remaining unselected word lines WL.

The address decoder 220 may apply a verify voltage generated in the voltage generation circuit 250 to a selected word line WL in a selected memory block in a program verify operation, and may apply the pass voltage Vpass to the remaining unselected word lines WL.

The address decoder 220 may be configured to decode a column address in the received address. The address decoder 220 may transmit the decoded column address to the read and write circuit 230.

A read operation and a program operation of the memory 110 may be performed by the unit of a page. An address received when a read operation or a program operation is requested may include at least one from among a block address, a row address and a column address.

The address decoder 220 may select one memory block and one word line depending on a block address and a row address. A column address may be decoded by the address decoder 220 and be provided to the read and write circuit 230.

The address decoder 220 may include at least one from among a block decoder, a row decoder, a column decoder and an address buffer.

The read and write circuit 230 may include a plurality of page buffers PB. The read and write circuit 230 may operate as a read circuit in a read operation of the memory cell array 210, and may operate as a write circuit in a write operation of the memory cell array 210.

The read and write circuit 230 described above may also be referred to as a page buffer circuit or a data register circuit that includes a plurality of page buffers PB. The read and write circuit 230 may include data buffers that take charge of a data processing function, and may further include cache buffers that take charge of a caching function.

The plurality of page buffers PB may be coupled to the memory cell array 210 through the plurality of bit lines BL. The plurality of page buffers PB may continuously supply sensing current to bit lines BL coupled with memory cells to sense threshold voltages (Vth) of the memory cells in a read operation and a program verify operation, and may latch sensing data by sensing, through sensing nodes, changes in the amounts of current flowing, depending on the programmed states of the corresponding memory cells.

The read and write circuit 230 may operate in response to page buffer control signals output from the control logic 240.

In a read operation, the read and write circuit 230 temporarily stores read data by sensing data of memory cells, and then, outputs data DATA to the input/output buffer of the memory 110. As an exemplary embodiment, the read and write circuit 230 may include a column select circuit in addition to the page buffers PB or the page registers.

The control logic 240 may be coupled with the address decoder 220, the read and write circuit 230 and the voltage generation circuit 250. The control logic 240 may receive a command CMD and a control signal CTRL through the input/output buffer of the memory 110.

The control logic 240 may be configured to control general operations of the memory 110 in response to the control signal CTRL. The control logic 240 may output control signals for adjusting the precharge potential levels of the sensing nodes of the plurality of page buffers PB.

The control logic 240 may control the read and write circuit 230 to perform a read operation of the memory cell array 210. The voltage generation circuit 250 may generate the read voltage Vread and the pass voltage Vpass used in a read operation, in response to a voltage generation circuit control signal output from the control logic 240.

Each memory block of the memory 110 described above may be configured by a plurality of pages corresponding to a plurality of word lines WL and a plurality of strings corresponding to a plurality of bit lines BL.

In a memory block BLK, a plurality of word lines WL and a plurality of bit lines BL may be disposed to intersect with each other. For example, each of the plurality of word lines WL may be disposed in a row direction, and each of the plurality of bit lines BL may be disposed in a column direction. In another example, each of the plurality of word lines WL may be disposed in a column direction, and each of the plurality of bit lines BL may be disposed in a row direction.

A memory cell may be coupled to one of the plurality of word lines WL and one of the plurality of bit lines BL. A transistor may be disposed in each memory cell.

For example, a transistor disposed in each memory cell may include a drain, a source, and a gate. The drain (or source) of the transistor may be coupled with a corresponding bit line BL directly or via another transistor. The source (or drain) of the transistor may be coupled with a source line (which may be the ground) directly or via another transistor. The gate of the transistor may include a floating gate, which is surrounded by a dielectric, and a control gate to which a gate voltage is applied from a word line WL.

In each memory block, a first select line (also referred to as a source select line or a drain select line) may be additionally disposed outside a first outermost word line more adjacent to the read and write circuit 230 between two outermost word lines, and a second select line (also referred to as a drain select line or a source select line) may be additionally disposed outside a second outermost word line between the two outermost word lines.

At least one dummy word line may be additionally disposed between the first outermost word line and the first select line. At least one dummy word line may also be additionally disposed between the second outermost word line and the second select line.

A read operation and a program operation (or write operation) of the memory block described above may be performed by the unit of a page, and an erase operation may be performed by the unit of a memory block.

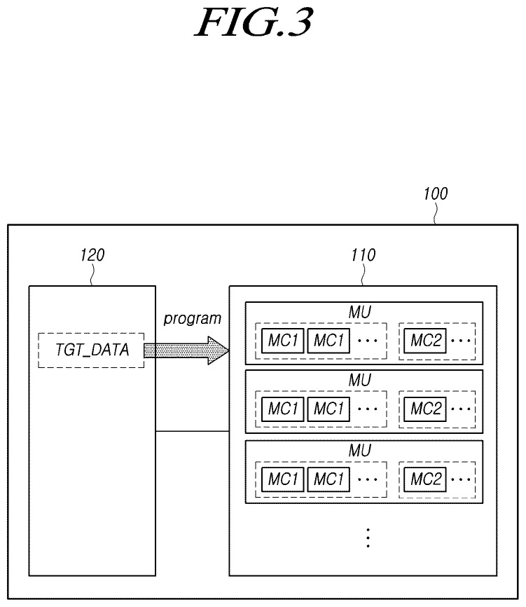

FIG. 3 illustrates a storage device 100 according to an embodiment of the present disclosure.

Referring to FIG. 3, the storage device 100 may include a memory 110 and a controller 120.

The memory 110 may include a plurality of memory units MU. Each of the plurality of memory units MU may store data of a predetermined size, such as 4 KB or 16 KB.

Each of the plurality of memory units MU may include a plurality of first memory cells MC1 and a plurality of second memory cells MC2. Each of the plurality of first memory cells MC1 may store data corresponding to first data bits, e.g., 2 bits or 3 bits, and each of the plurality of second memory cells MC2 may store data corresponding to second data bits, e.g., 1 bit. The number of first data bits and the number of second data bits may be the same as or different from each other.

The controller 120 may program target data TGT_DATA into the memory 110. For example, the target data TGT_DATA may include data received from an external device, such as a host connected to the storage device 100. For another example, the target data TGT_DATA may include data migrated from a specific area of the memory 110 to another area.

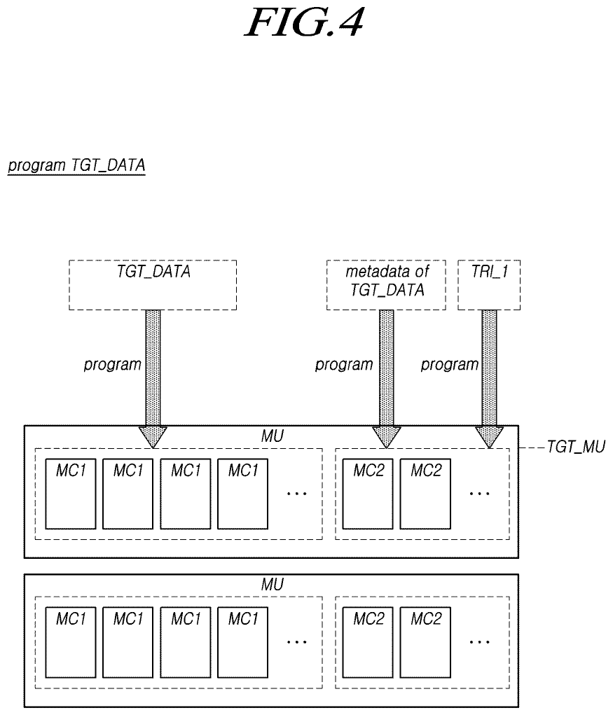

FIG. 4 illustrates an operation in which the storage device 100 according to the embodiment of the present disclosure programs the target data TGT_DATA into a target memory unit TGT_MU.

Referring to FIG. 4, the controller 120 of the storage device 100 may program the target data TGT_DATA into first memory cells MC1 included in the target memory unit TGT_MU among the plurality of memory units MU included in the memory 110.

The controller 120 may program first temperature range information TRI_1, representing a temperature range at the time of programming the target data TGT_DATA, into second memory cells MC2 included in the target memory unit TGT_MU. That is to say, the controller 120 may store both the target data TGT_DATA and the first temperature range information TRI_1 together in the target memory unit TGT_MU.

The temperature at the time of programming the target data TGT_DATA can be determined using various methods.

For example, the controller 120 may include a temperature storage unit (not illustrated) that stores the temperature of the memory 110. For example, the temperature storage unit may be a volatile memory capable of storing data of a set number of bits.

The controller 120 may periodically obtain the temperature of the memory 110 from a temperature sensor (not illustrated) that measures the temperature of the memory 110, and may update the temperature stored in the temperature storage unit at a preset interval (e.g., every 1 second).

The controller 120 may determine the first temperature range information TRI_1 based on the temperature stored in the temperature storage unit at the time of programming the target data TGT_DATA.

The first temperature range information TRI_1 may represent one of a plurality of temperature ranges. Due to the limited storage capacity of the second memory cells MC2, directly storing an exact temperature value at the time of programming the target data TGT_DATA may not be feasible. Instead, the controller 120 may determine the first temperature range information TRI_1 based on the temperature value at the time of programming the target data TGT_DATA and store the first temperature range information TRI_1 in the second memory cells MC.

For example, if expressing the full temperature value requires at least 9 data bits, the controller 120 may instead store the first temperature range information TRI_1 in the second memory cells MC2, which can be represented using only 1 to 2 bits.

The second memory cells MC2 included in the target memory unit TGT_MU are memory cells to which metadata for the target data TGT_DATA is programmed. In other words, the controller 120 may store the metadata for the target data TGT_DATA in the second memory cells MC2 included in the target memory unit TGT_MU.

An area composed of the second memory cells MC2 within the target memory unit TGT_MU may be referred to as a spare area.

By storing the first temperature range information TRI_1 in the second memory cells MC2 within the target memory unit TGT_MU, the controller 120 eliminates the need to record, in a separate area, information on the temperature at the time of programming the target data TGT_DATA.

In addition, since the first temperature range information TRI_1 is determined by reflecting the temperature at the time of programming the target data TGT_DATA, the temperature characteristics of the target memory unit TGT_MU can be more accurately represented.

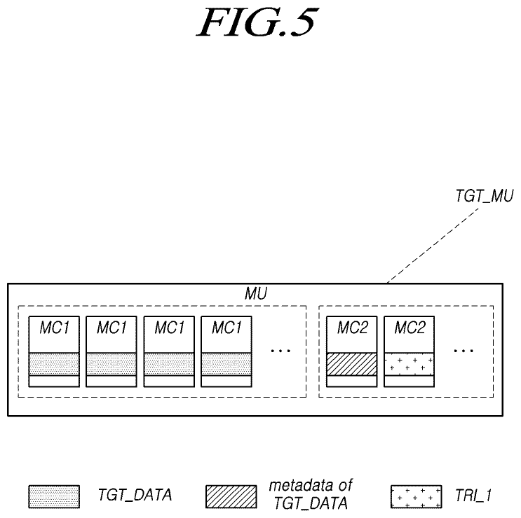

FIG. 5 illustrates data programmed into the target memory unit TGT_MU according to an embodiment of the present disclosure.

Referring to FIG. 5, the target data TGT_DATA may be stored in the first memory cells MC1 of the target memory unit TGT_MU.

The metadata corresponding to the target data TGT_DATA and the first temperature range information TRI_1 may be stored together in the second memory cells MC2 of the target memory unit TGT_MU.

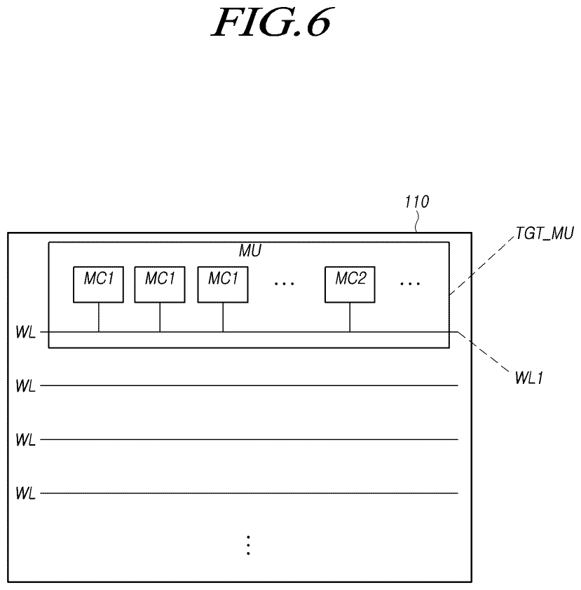

The target memory unit TGT_MU may be implemented in various structures. This will be described in detail below with reference to FIG. 6.

FIG. 6 illustrates an example of the target memory unit TGT_MU according to an embodiment of the present disclosure.

Referring to FIG. 6, the memory 110 may include a plurality of word lines WL. A plurality of memory cells may be arranged on each of the plurality of word lines WL.

The first memory cells MC1 and the second memory cells MC2 included in the target memory unit TGT_MU may be connected to a single word line, e.g., a first word line WL1, among the plurality of word lines WL. Namely, the target memory unit TGT_MU may be composed of memory cells that are connected to the same word line.

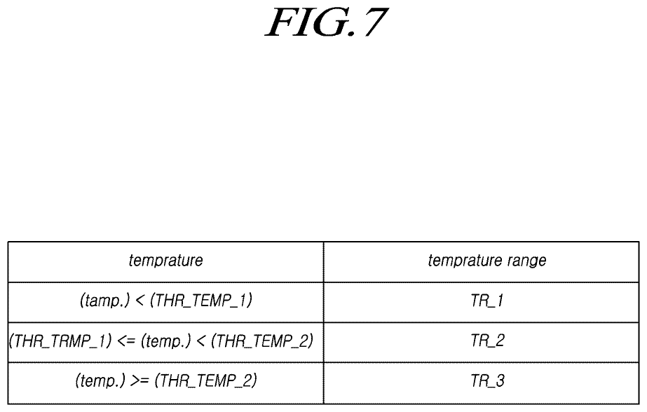

As described above, temperature range information may represent one of a plurality of temperature ranges. This will be described in detail below with reference to FIG. 7.

FIG. 7 illustrates an example in which the storage device 100 according to the embodiment of the present disclosure determines temperature range information.

Referring to FIG. 7, the temperature range information may represent a first temperature range TR_1, a second temperature range TR_2, or a third temperature range TR_3.

The first temperature range TR_1 corresponds to a temperature lower than a first threshold temperature THR_TEMP_1. The first temperature range TR_1 may represent a cold temperature range.

The second temperature range TR_2 corresponds to a temperature equal to or higher than the first threshold temperature THR_TEMP_1 and lower than a second threshold temperature THR_TEMP_2. The second temperature range TR_2 may represent a room temperature range.

The third temperature range TR_3 corresponds to a temperature equal to or higher than the second threshold temperature THR_TEMP_2. The third temperature range TR_3 may represent a hot temperature range.

In this case, the value of the first temperature range information TRI_1 may represent either the first temperature range TR_1, the second temperature range TR_2, or the third temperature range TR_3.

The storage device 100 may determine the temperature range information using a method other than the one described in the embodiment referenced in FIG. 7.

For example, the temperature range information may represent a low temperature range or a high temperature range. The low temperature range may correspond to a temperature lower than a threshold temperature, and the high temperature range may correspond to a temperature equal to or higher than the threshold temperature.

In the above, an operation has been described in which the storage device 100 programs the target data TGT_DATA to the target memory unit TGT_MU along with the temperature range information at the time of programming the target data TGT_DATA.

Hereinbelow, an operation in which the storage device 100 reads the target data TGT_DATA programmed into the target memory unit TGT_MU will be described.

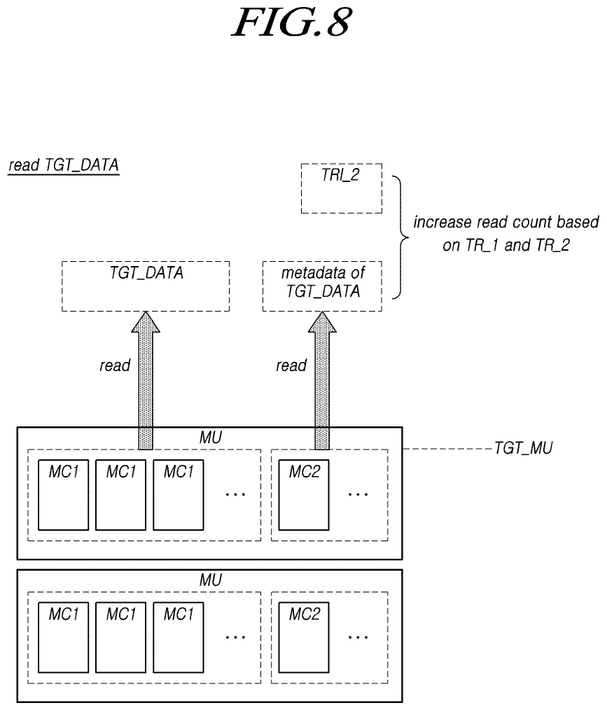

FIG. 8 illustrates an operation in which the storage device 100 according to the embodiment of the present disclosure reads the target data TGT_DATA from the target memory unit TGT_MU.

Referring to FIG. 8, the controller 120 of the storage device 100 may read the target data TGT_DATA from the first memory cells MC1 within the target memory unit TGT_MU.

The controller 120 may read the first temperature range information TRI_1 from the second memory cells MC2 within the target memory unit TGT_MU.

The controller 120 may determine an increase amount in read count for the target data TGT_DATA based on the first temperature range information TRI_1 and second temperature range information TRI_2. The read count indicates the extent to which the target data TGT_DATA has been read.

The second temperature range information TRI_2 is temperature range information at the time of reading the target data TGT_DATA.

Similar to the first temperature range information TRI_1, the controller 120 may determine the second temperature range information TRI_2 based on a temperature stored in the temperature storage unit (not illustrated) at the time of reading the target data TGT_DATA.

An increase amount in read count for the target data TGT_DATA influences the determination of the timing for executing a defense operation at preventing the deterioration of the reliability of the target data TGT_DATA (e.g., migrating the target data TGT_DATA to another memory unit). The optimal timing for executing the defense operation for the target data TGT_DATA may be determined based on the temperature at the time when the target data TGT_DATA is programmed and the temperature at the time when the target data TGT_DATA is read.

For example, if the target data TGT_DATA is programmed in a high temperature environment and later read in a low temperature environment, the reliability of the target data TGT_DATA may decrease significantly due to the read operation. Therefore, in order to prevent a failure, the controller 120 needs to execute the defense operation earlier than originally planned.

On the other hand, if the target data TGT_DATA is programmed and read in a room temperature environment, the decrease in the reliability of the target data TGT_DATA due to the read operation is small. Therefore, the controller 120 does not need to unnecessarily advance the timing of the defense operation, thus avoiding an increase in the overhead caused by the defense operation.

Accordingly, based on the first temperature range information TRI_1, which represents the temperature at the time when the target data TGT_DATA is programmed, and the second temperature range information TRI_2, which represents the temperature at the time when the target data TGT_DATA is read, the controller 120 may select an appropriate increase amount in read count for the target data TGT_DATA. This selection allows the controller 120 to optimize the timing of the defense operation. As a result, the controller 120 can prevent a failure of the target data TGT_DATA from occurring earlier than expected, while also minimizing the overhead associated with the defense operation for the target data TGT_DATA.

Meanwhile, the controller 120 may also use the first temperature range information TRI_1 and the second temperature range information TRI_2 instead of an increase amount in read count to determine whether the target memory unit TGT_MU has failed. For example, if the first temperature range information TRI_1 indicates the highest temperature range, the controller 120 may adjust a reference for determining the failure of the target memory unit TGT_MU (e.g., by changing the threshold for the number of bits that have failed during a process of reading the target data TGT_DATA).

Hereafter, a specific method by which the storage device 100 determines an increase amount in read count for the target data TGT_DATA will be described.

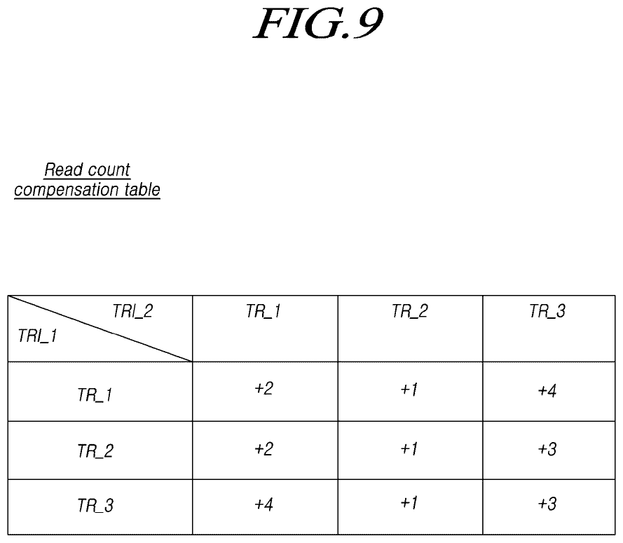

FIG. 9 illustrates an example of an operation in which the storage device 100 according to the embodiment of the present disclosure determines an increase amount in read count.

Referring to FIG. 9, the controller 120 of the storage device 100 may determine an increase amount in read count for the target data TGT_DATA based on a read count compensation table. This table specifies increase amounts in read count corresponding to the pair of the first temperature range information TRI_1 and the second temperature range information TRI_2.

In FIG. 9, each of the first temperature range information TRI_1 and the second temperature range information TRI_2 may indicate a first temperature range TR_1, a second temperature range TR_2, or a third temperature range TR_3.

When the first temperature range information TRI_1 indicates the first temperature range TR_1 and the second temperature range information TRI_2 indicates the first temperature range TR_1, an increase amount in read count is +2.

When the first temperature range information TRI_1 indicates the second temperature range TR_2 and the second temperature range information TRI_2 indicates the first temperature range TR_1, an increase amount in read count is +2.

When the first temperature range information TRI_1 indicates the third temperature range TR_3 and the second temperature range information TRI_2 indicates the first temperature range TR_1, an increase amount in read count is +4.

When the first temperature range information TRI_1 indicates the first temperature range TR_1 and the second temperature range information TRI_2 indicates the second temperature range TR_2, an increase amount in read count is +1.

When the first temperature range information TRI_1 indicates the second temperature range TR_2 and the second temperature range information TRI_2 indicates the second temperature range TR_2, an increase amount in read count is +1.

When the first temperature range information TRI_1 indicates the third temperature range TR_3 and the second temperature range information TRI_2 indicates the second temperature range TR_2, an increase amount in read count is +1.

When the first temperature range information TRI_1 indicates the first temperature range TR_1 and the second temperature range information TRI_2 indicates the third temperature range TR_3, an increase amount in read count is +4.

When the first temperature range information TRI_1 indicates the second temperature range TR_2 and the second temperature range information TRI_2 indicates the third temperature range TR_3, an increase amount in read count is +3.

When the first temperature range information TRI_1 indicates the third temperature range TR_3 and the second temperature range information TRI_2 indicates the third temperature range TR_3, an increase amount in read count is +3.

In the embodiments of the present disclosure, the specific values of the increase amounts in read count, based on the pair of the first temperature range information TRI_1 and the second temperature range information TRI_2, are not limited to the example shown in FIG. 9 and may be determined in a different way.

For example, the controller 120 may determine an increase amount in read count to be greater when the second temperature range information TRI_2 indicates the second temperature range TR_2 compared to when the second temperature range information TRI_2 indicates the first temperature range TR_1 or the third temperature range TR_3.

For another example, the controller 120 may determine an increase amount in read count to be greater when a temperature range indicated by the first temperature range information TRI_1 differs from a temperature range indicated by the second temperature range information TRI_2, compared to when the temperature range indicated by the first temperature range information TRI_1 is the same as the temperature range indicated by the second temperature range information TRI_2.

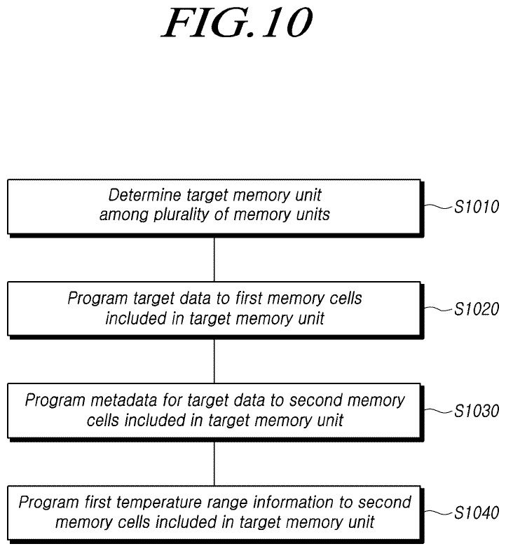

FIG. 10 illustrates a method for operating a storage device 100 according to an embodiment of the present disclosure.

Referring to FIG. 10, the method for operating the storage device 100 may include step S1010, which involves determining a target memory unit TGT_MU among a plurality of memory units MU included in a memory 110. Each of the plurality of memory units MU may include a plurality of first memory cells MC1 and a plurality of second memory cells MC2.

The method for operating the storage device 100 may include step S1020, which involves programming target data TGT_DATA into first memory cells MC1 included in the target memory unit TGT_MU.

The method for operating the storage device 100 may include step S1030, which involves programming metadata corresponding to the target data TGT_DATA into second memory cells MC2 included in the target memory unit TGT_MU.

The method for operating the storage device 100 may include step S1040, which involves programming first temperature range information TRI_1 into second memory cells MC2 included in the target memory unit TGT_MU. The first temperature range information TRI_1 represents a temperature range at the time of programming the target data TGT_DATA.

For example, temperature range information may indicate a first temperature range TR_1, a second temperature range TR_2, or a third temperature range TR_3. The first temperature range TR_1 corresponds to a temperature below a first threshold temperature THR_TEMP_1. The second temperature range TR_2 corresponds to a temperature equal to or higher than the first threshold temperature THR_TEMP_1 and lower than a second threshold temperature THR_TEMP_2. The third temperature range TR_3 corresponds to a temperature equal to or higher than the second threshold temperature THR_TEMP_2.

The method for operating the storage device 100 may further include reading the target data TGT_DATA from the first memory cells MC1 included in the target memory unit TGT_MU, reading the first temperature range information TRI_1 from the second memory cells MC2 included in the target memory unit TGT_MU, and determining an increase amount in read count for the target data TGT_DATA based on the first temperature range information TRI_1 and second temperature range information TRI_2.

For example, the determining an increase amount in read count for the target data TGT_DATA may include determining an increase amount in read count for the target data TGT_DATA based on a read count compensation table, which specifies increase amounts in read count depending on the pair of the first temperature range information TRI_1 and the second temperature range information TRI_2.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A storage device, comprising:
a memory including a plurality of memory units, each of the plurality of memory units including a plurality of first memory cells and a plurality of second memory cells; and
a controller configured to program target data into first memory cells within a target memory unit among the plurality of memory units, program metadata corresponding to the target data into second memory cells within the target memory unit, and program first temperature range information, representing a temperature range at a time of programming the target data, into second memory cells within the target memory unit.

2. The storage device according to claim 1, wherein
the memory includes a plurality of word lines, and
the first memory cells and the second memory cells within the target memory unit are connected to a first word line among the plurality of word lines.

3. The storage device according to claim 1, wherein:
temperature range information indicates a first temperature range, a second temperature range, or a third temperature range,
the first temperature range corresponds to a temperature lower than a first threshold temperature,
the second temperature range corresponds to a temperature equal to or higher than the first threshold temperature and lower than a second threshold temperature, and
the third temperature range corresponds to a temperature equal to or higher than the second threshold temperature.

4. The storage device according to claim 1, wherein the controller is configured to:
read the target data from the first memory cells within the target memory unit,
read the first temperature range information from the second memory cells within the target memory unit, and
determine an increase amount in read count for the target data based on the first temperature range information and second temperature range information, which represents a temperature range at a time of reading the target data.

5. The storage device according to claim 4, wherein the controller determines the increase amount in read count for the target data based on a read count compensation table that specifies increase amounts in read count corresponding to pairs of the first temperature range information and the second temperature range information.

6. A method for operating a storage device, the method comprising:
determining a target memory unit among a plurality of memory units included in a memory, each of the plurality of memory units including a plurality of first memory cells and a plurality of second memory cells;
programming target data into first memory cells within the target memory unit;
programming metadata corresponding to the target data into second memory cells within the target memory unit; and
programming first temperature range information, representing a temperature range at a time of programming the target data, into second memory cells within the target memory unit.

7. The method according to claim 6, wherein:
temperature range information indicates a first temperature range, a second temperature range, or a third temperature range,
the first temperature range corresponds to a temperature lower than a first threshold temperature,
the second temperature range corresponds to a temperature equal to or higher than the first threshold temperature and lower than a second threshold temperature, and
the third temperature range corresponds to a temperature equal to or higher than the second threshold temperature.

8. The method according to claim 6, further comprising:
reading the target data from the first memory cells within the target memory unit;
reading the first temperature range information from the second memory cells within the target memory unit; and
determining an increase amount in read count for the target data based on the first temperature range information and second temperature range information, which represents a temperature range at a time of reading the target data.

9. The method according to claim 8, wherein the determining an increase amount in read count for the target data includes determining the increase amount in read count for the target data based on a read count compensation table that specifies increase amounts in read count corresponding to pairs of the first temperature range information and the second temperature range information.
